(19) United States
(12) Patent Application Publication
(10) Pub. No.: US 2009/0260670 A1
(43) Pub. Date: Oct. 22, 2009

(54) Precursor ink for producing IB-IIIA-VIA semiconductors

(76) Inventor: Xiao-Chang Charles Li, (US)

Correspondence Address: X. Charles Li, 200 Ludlow Dr. STEC., Ewing, NJ, 08638, US

(21) Appl. No.: 12/148,468

(22) Filed: Apr. 18, 2008

(51) Int. Cl. C09D 11/02; H01L 21/00; H01L 31/00

(52) U.S. Cl. 136/244; 438/95; 136/258; 106/31.13; 257/E21.001

(57) ABSTRACT

Copper indium diselenide, copper indium gallium diselenide, and other IB-IIIA-VIA compounds are produced by the liquid deposition on a substrate of a precursor-containing ink, followed by heating to produce the desired material. The precursor containing ink is a mixture of three parts. The first part is plurality of particulates of metal compounds of IB, IIIA. The second part is chalcogen source of selenium, sulfur, or organic chalcogen compounds dissolved in a liquid organic solvent. The third part solution function as viscosity adjustment, as introduction of dopant of sodium ion and/or as ink stabilizer. The precursor ink can be coated on substrate at room temperature and it can be transferred into copper indium (gallium) chalcogenide semiconductor thin film upon baking and a chalcogenization process. The resulting thin film semiconducting material can be incorporated into photovoltaic and other electronic devices.

### BACKGROUND OF THE INVENTION

1. Field of the Invention

The present invention relates to an ink formulation and its use for synthesis and preparation of copper indium diselenide, copper indium gallium diselenide, and other IB-IIIA-VIA semiconductor compounds by the liquid deposition on a substrate, followed by heating to produce the desired material. The resulting thin film semiconducting material can be incorporated into photovoltaic and other electronic devices.

2. Description of the Related Art

Copper indium gallium diselenide (CuInₓGa₁₋ₓSe₂ for 0≦x≦1, often called CIGS) is a IB-IIIA-VIA semiconducting material used in thin film solar cells, due to its favorable electrical and optical properties, stability, and inexpensive means of production. Energy conversion efficiencies of 19% have been achieved for a CIGS-based solar cell. (See Ramanathan et al., “CIGS Thin-Film Solar Cell Research at NREL: FY04 Results and Accomplishments,” 2004 DOE Solar Energy Technologies Program Review Meeting, 2004.) The active semiconductor layers are typically fabricated using vapor phase deposition processes such as vacuum evaporation, sputtering and chemical vapor deposition. However, it is difficult to deposit uniform films with exact atomic ratios on large areas using vapor phase processes.

To overcome these hurdles and to achieve a better control of the Cu/(In+Ga) ratio throughout the film, attempts have been made to fix this ratio in a material before the deposition process, and then transfer this fixed composition into the thin film formed using the material. One initial attempt was a screen printing technique that use a paste of milled fine powder of Cu, In and Se in the compositional ratio of 1:1:2 to form a preliminary Cu—In—Se film on a borosilicate glass substrate, followed heating to 700° C. in a nitrogen atmosphere to form a semiconductor compound film of CuInSe₂ (T. Arita et al, 20^{th} IEEE PV Specialists conference, 1988, page 1650). Due to the large particle size (up to 2 μm), and the high sintering temperature, which causes indium loss and deforms the soda-lime glass substrate, PV performance was reported to be low, with efficiencies of only about 1%. Also, In(OH)₃ or In₂O₃ may form in the sintered films, as indium powder easily oxidizes at high temperatures in the presence of trace amounts of oxygen.

Mixed-metal chalcogenide nanoparticles have been prepared by reacting iodides of copper and indium with sodium selenide in an organic solvent bath system such as a mixture of pyridine and methanol, as in Schultz et al., U.S. Pat. No. 6,126,740. Nanoparticles of CuInGaSe₂ in the range of 10-30 nm can be obtained, and their suspension in mixture solvent of pyridine/methanol was sprayed directly onto a molybdenum coated soda-lime glass substrate heated to 144° C. With this technology, a film with fixed ratios of the four elements is readily achieved. However, the CIGS nanoparticles are largely amorphous, which is not desirable for high performance photovoltaic cell. The amorphous condition of the particles may be due to the fast reaction between the iodides and sodium selenide in the pyridine-methanol medium. Also, the large quantity of sodium iodide byproduct may interfere the formation of crystalline particles.

Recently, Kapur et al. disclosed an oxide-based method of making IB-IIIA-VIA semiconductor compounds (U.S. Pat. No. 6,127,202) in which an ink of oxide-containing particles including Group IB and IIIA elements is formed by pyrolyzing metal nitrates or sulfates of IB and IIIA elements (such as copper and indium) into fine oxide particles. A non-vacuum solution coating method can produce a thin film of Cu₂In₂O₅ from these particles, and the film can be transformed to Cu₂In₂Se₅ by treatment in hydrogen, hydrogen selenide, or both at an elevated temperature (425-550° C.). Similarly, Cu₂In₂₋ₓGaₓO₅ can be formed and transformed into a CuInGaSe₂ film as disclosed by Eberspacher et al (U.S. Pat. No. 6,268,014). Both techniques utilize the non-volatility of the oxides of IB and IIIA metals, and chemically reduce the oxides while adding selenium to form an IB-IIIA-VIA thin film. Although precise control of the IB/IIIA elemental ratio is readily achieved by this method, full control of the reduction and “selenization” of the oxides is still difficult. Besides, thus formed films often show rough surface and even void morphology due to the loose binding strength of the oxide. Although this poor mechanical strength of the oxides can be improved by adding polymeric binder, advert effect of the polymer binder on electronic properties are encountered.

To overcome the non-uniformity and the void problems associated with IB-IIIA oxides, a most recent disclosure utilizes non-oxide nanoparticles of IB-IIIA-VIA that are coated with one or more layers of indium metal. (Brian M. Sager, et al, U.S. Pat. No. 7,306,823) Dense precursor films of IB-IIIA-VIA are expected to form upon heating the coated nanoparticles.

Thus, there is a need in the art, for better preparation techniques for precursor ink of IB-IIIA-VIA to scale up manufacturing of good quality thin film semiconductors, such as copper-Indium-gallium diselenide (CIGS).

### SUMMARY OF THE INVENTION

The disadvantages associated with the prior art are overcome by embodiments of this invention directed to the ink formulation of particulates of metal sources of IB and IIIA as elemental metal forms, or their oxides, chalcogenides, carboxylic salts or sulfonate salts, dispersed in a mixture liquid of a dilution solvent and a solvent dissolved with selenium or sulfur. In one of the embodiments, polycrystalline Cu(InₐGa_{b}Al_{c})Se_{y}S_{2-y}, where 0.7<a+b+c<1.3 and 0<y≦2, is produced from an ink by first mixing a liquid organic compound containing phosphorus, sulfur or oxygen in which selenium, sulfur or both have been dissolved, with a mixture of particulates containing IB, IIB, IIIA compounds. The particulates can be one or more compounds of metals, such as compounds of sulfonates, carboxylates or oxides. A dilution solvent may or may not be present in the ink suspension. The size of the particulates is within 5 nm to 3000 nm, and desirably within 50 nm to 1000 nm.

The ink is applied to a substrate as a liquid or a liquid suspension and dried in a vacuum to remove all the solvents (the dilution solvent and the solvent for selenium or sulfur). The substrate may be heated to a temperature that sufficient high to remove the solvent and to melt the selenium or sulfur to bind the particulates of the metal compounds and lead to the formation of dry and smooth film with well-controlled stoichiometry among the metal compounds. The ink coating process can be fulfilled by various means known to those with ordinary skills, such as dip-coating, spin-coating, blade coating, rod-coating, spraying, brushing, screen-printing, contact-printing, ink-jet printing etc. The dried substrate and coating are then heated for chalcogenization, producing thin film polycrystalline Cu(InₐGa_{b}Al_{c})Se_{y}S_{2-y} with the desired composition and good uniformity. This film can be used as a semiconducting layer in thin film photovoltaic cells.

### DESCRIPTION OF THE DRAWINGS

FIG. 1 is an illustration of formulating the precursor ink 103 by mixing particulates of IB, IIB and IIIA elements containing compound particulates 100, liquid chalcogen solution 101 and a main solvent 102.

FIG. 2 is an illustration of the process using the precursor ink 103 to form wet coating 104 by a solution coating process, and a dry film 105 if formed upon baking 104, and the formation of CIGSeS semiconductor film 106 after chalcogenization of 105.

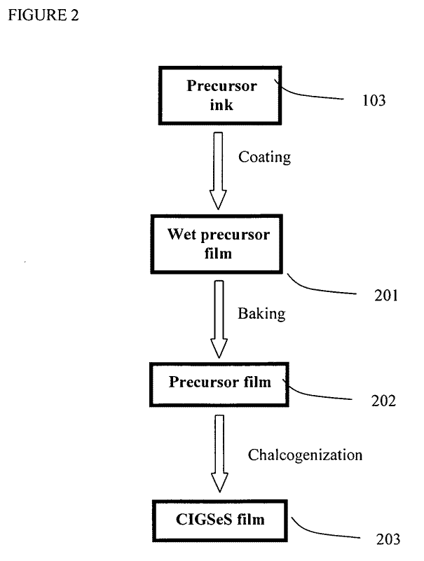

FIG. 3 is an illustration of band gap of Cu(InAl)Se₂, Cu(InGa)Se₂ and CuIn(SeS)₂ with x=Al/(In+Al), Ga/(In+Ga) or S/(S+Se), respectively.

### DETAILED DESCRIPTION OF THE INVENTION

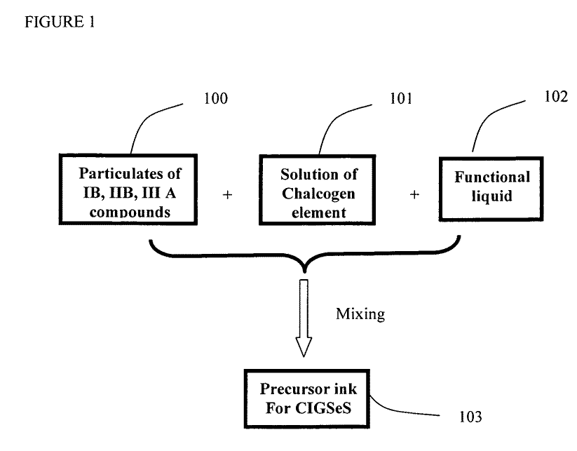

The present invention is directed to the general design and preparation of a precursor ink of multi-metal chalcogenide semiconductor with tailored band gap and precise control of elements and their ratios, as well as its solution processing application for optoelectronic thin film devices such as photovoltaic devices (solar cells). The precursor ink within the scope of the present invention may have a general formula as shown in FIG. 1:
Particulates of one or more metal compounds+one or more liquid chalcogen+One functional liquid

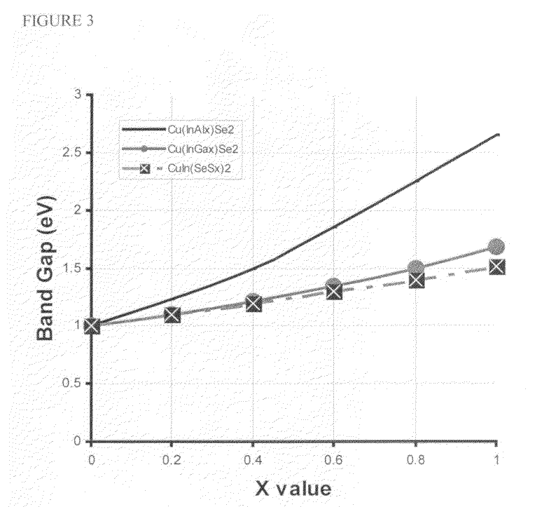

The tailored band gap means that the band gap of the semiconductor film should be within 1.0-1.5 eV as this range of band gap can maximally absorb sunlight (with the wavelength of 400 nm to 1200 nm). Although many metal chalcogenides can meet with the band gap requirements, it is preferably to use IB, IIB and IIIA metals for the purpose of this invention. Most desirably, metals like Cu, Cd, Zn, In, Ga and Al are particularly useful for the purpose of this invention. In one of the embodiments of this invention, polycrystalline Cu(InₐGa_{b}Al_{c})Se_{y}S_{2-y} is selected to fulfill the purpose of the PV application. As shown in FIG. 3, various band gaps can be achieved by changing the metal composition ratio of the stoichiometry of the metals. The metal source means the particle or particle mixture of one or more metal compounds. Metal compounds may be any form of metal compounds containing IB, IIB and IIIA. The metal compounds may be oxides, such as copper oxide, indium oxide, gallium oxide; or hydroxides such as copper hydroxide, indium hydroxide, gallium hydroxide; or carboxylic salts such as copper acetate, indium acetate, gallium acetate; or metal sulfides such as copper sulfide, indium sulfide, gallium sulfide; or metal selenides such as copper selenide, indium selenide and gallium selenide; or metal halides such as copper chloride, indium chloride, gallium chloride, copper bromide, indium bromide, gallium bromide, copper iodide, indium iodide, gallium iodide; or metal nitrates such as copper nitrate, indium nitrate, gallium nitrate; or metal acetylacetonates such as copper acetylacetonate, indium acetylacetonate, gallium acetylacetonate; or metal sulfates such as copper sulfate, indium sulfate, gallium sulfate; or metal triflates such as copper triflate, indium triflate, gallium triflate. It is within the scope of this invention that the metal source may be a mixture of various forms of metal source, such as the combination of copper powder with indium selenide, or copper sulfide with indium chloride, etc. The size of the particulates should be smaller than 2000 nm in order to form thin film with about 1 to 3 micrometer thickness, and desirably within the range of 5 nm-1000 nm to achieve ink printed film with good uniformity, and mostly preferably with the size less than 500 nm.

The precursor ink contains at least one liquid chalcogen, such as liquid selenium or liquid sulfur. Here liquid means a liquid solvent that dissolves selenium and/or sulfur. In one embodiments of this invention is a liquid solvent containing heteroatom N, P, O that can readily dissolve selenium or sulfur. For instance, both selenium and sulfur can be easily dissolved in ethylenediamine and trioctyl phosphine. It is also within the scope of this invention that the liquid chalcogen is a liquid compound. These liquid chalcogen compounds may have a general formula of R1SeR2, R1SeSeR2, R1SR2, R1SSR2, R1SeSR2 (R1 and R2 being hydrocarbon with carbon number of less than 10). Examples are diethyl diselenide, diethyl selenide, dipropyl diselenide, dipropyl selenide, diethyl sulfide, dipropyl disulfide, dibutyl selenide, dibutyl diselenide, dibutyl sulfide, dibutyl disulfide, etc. The benefit of using liquid chalcogen is that the chalcogen, such as selenium, can be the best binder of particulates upon the evaporation of solvent, and can be the active reactant for the chalcogenization process to form CIGS semiconductor.

Ink is defined as a “pigmented liquid” and paint is defined as a “liquid mixture, usually of a solid pigment suspended in a liquid vehicle”. Ink in this disclosure may be regarded as a paint, or paste if it is really more viscous and with more solid content compared to the liquid vehicle. Under vigorous stirring condition, the mixture of particulates of metal compounds of IB, IIB and IIIA can readily dispersed in liquid chalcogen solution. To prevent fast precipitation of the particulates, fine particles of the metal compounds are desirable with the size in a nano scale, preferably between 5 nm to 1000 nm, and most preferably between 5 nm to 300 nm. Various high purity nanoparticles of metal compounds, such as metal oxides and metal sulfides are commercially available and they can be used directly. In case of commercially unavailable, fine particulates of metal compounds can be readily prepared by using ball milling process in a liquid vehicle, or prepared through other methods know to the prior art. When used with rod-coating, dip-coating, or screen printing to achieve about desirable thickness of CIGS, preferably from 1 to 3 micrometer thickness film, the ink can have a very high viscosity, up to 90,000 cp, preferably up to 70,000 cp, and more preferably between 500 to 10,000 cp. It is therefore common to use another liquid that is mixable with the liquid chalcogen as a dilution solution to adjust viscosity and solid to liquid ratio. The solid to liquid ratio for the ink in this invention is generally between 10-75% (g/mL), preferably between 15-50% (g/mL).

The dilution solvent functions as an adjusting reagent for viscosity and for solid to liquid ratio. The dilution solvent can also function as a stabilizer for the ink, preventing from too easy precipitation or preventing from too fast drying during process. The dilution solvent generally has a boiling point between 90° C. to 500° C., and is generally selected from organic solvents with carbon numbers of 3 to 30. One classes of them is hydrocarbon, such as hexane, cyclic hexane; or selected from an alcohol, such as isopropanol; or from acetate, such as butyl acetate; or a phosphorus containing liquid, such as trioctyl phosphine, trioctyl phosphine oxide; or from an aromatic liquid, such as xylene; or from a N-containing solvent, such as ethylenediamine, N,N-dimethylacetamide (DMAC), N-methyl pyrrolidone; or a carboxylic acid, such as acetic acid. More preferably, the dilution solvent is selected from those containing heteroatom N, P and O.

To obtain highly efficient CIGS solar cells, a sodium ion dopant may be added to the precursor ink. The addition of sodium ion can promote the growth of crystalline CIGS and lead to larger crystalline grain size. The sodium dopant may be selected from a sodium salt. Various sodium salts can be used and one class of them is sodium halide, such as NaCl, NaF, NaI; or a sodium chalcogenide, such as Na₂S, Na₂Se, Na₂Te; or a carboxylic sodium, a sodium sulfonate, a sodium salt of polyacrylic acid, etc. The amount of sodium ion is preferably in the range of 0.1% to 5% (wt/wt), and more preferably in the range of 0.5% to 2%.

Thus formulated CIGS precursor ink can be used to coat thin film layer on a substrate, such as a glass, a metal foil, or a polymer film. For solar cell application, a thin layer of molybdenum metal (thickness of 0.2-1.2 micrometer) is usually coated on the substrate as a mirror and a bottom electrode. The CIGS precursor ink can be coated on a molybdenum coated substrate, for instance, a soda-lime glass substrate, by means of wet solution coating process, such as a dipping coating, blade coating, brush coating, spray coating, rod coating, screen printing, or a contact stamping, etc. The wet film needs be dried by baking at elevated temperature, preferably between 50-500° C., and most preferably between 100-300° C. A pressure of positive or negative one can be applied during this baking process. A negative pressure, or a vacuum pressure can be desirably to apply to quickly dry the film. Upon the evaporation of the solvent and the dilution solvent, selenium or sulfur is remained with good mixing with the particulate metal compound powder. The film formed is both smooth and dense with controlled ratio of metals. The dry film is then subject to a chalcogenization (meaning either selenization or sulfurization) process to drive the reaction between the metal compound powder and the chalcogen remained in the film to form semiconductor CIGSeS. The chalcogenization is preferably carried out in the atmosphere of chalcogen vapor (such as selenium vapor or sulfur vapor), or in an atmosphere containing hydrogen chalcogenide (i.e. hydrogen selenide or hydrogen sulfide), or in the atmosphere containing other chalcogen source, such as diethyl selenide, diethyl sulfide, etc. The chalcogenization process is usually carried out at elevated temperature from 350° C. to 600° C., and preferably at temperature of 400-550° C.

### PREFERRED EMBODIMENTS

The following three examples are given as embodiments of the invention for preparing the precursor ink and for producing Cu(InₐGa_{b})Se_{y}S_{2-y}, which can then be used in photovoltaic cells. Variations on these embodiments, and similar embodiments covered by the claims, will be apparent to those skilled in the art. The embodiments do not preclude the use of Cu(InₐGa_{b}Al_{c})Se_{y}S_{2-y} produced by the methods described for other applications.

### Embodiment 1

A mixture of 0.334 g of copper acetate, 0.413 g of indium acetate, and 0.223 g of gallium acetone acetate is ball-milled in the liquid of isopropanol (8 mL) into fine particle (with size less than 0.8 micrometer) and then mixed in a solution of selenium (0.319 g dissolved in 5 ml of trioctyl phosphine) in trioctyl phophine to form the precursor Ink 1.

A molybdenum-coated soda-lime glass substrate is dipped in Ink 1 at room temperature, and the coated substrate is dried in a vacuum at 220° C. for 2 hours. The dried substrate is then sealed in an autoclave and heated to 500° C. in argon. This reaction forms a copper-indium-gallium diselenide (CIGS) film with a thickness of about 2 μm and a composition of CuIn_{0.77}Ga_{0.33}Se_{2.1}. This film can form a light absorbing semiconducting layer for a thin film photovoltaic cell.

### Embodiment 2

A mixture of 3.18 g of copper oxide nanoparticles (diameter less than 0.2 micrometer) and 5.55 g of indium oxide nanoparticles diameter less than 0.2 micrometer) is suspended in a solution of 44 g of pentacanoic acid in 20 mL of butyl acetate. This suspension is mixed into a solution of 6.32 g of selenium in 40 ml of trioctyl phosphine to form the precursor Ink 2.

A molybdenum coated soda-lime glass substrate is coated with Ink 2 while spinning, and the coated substrate is vacuum dried at 220° C. for 2 hours. The dried substrate is sealed in an autoclave chamber and heated to 500° C. in argon. The copper, indium and gallium in the film react to form a 2 μm film of CuInSe₂. This film can form a light absorbing semiconducting layer for a thin film photovoltaic cell.

### Embodiment 3

A solution of selenium is prepared by adding 1.74 g selenium into the solvent of trioctylphophine (10 mL) and stirred for 3 days. A mixture of 0.80 g of copper oxide nanoparticles and 1.39 g of indium oxide nanoparticles is suspended in the selenium solution in trioctylphophine. A dilution solution of ethyl acetate (3 mL) is added into the solution to adjust thickness. And polyacrylic acid (with sodium) (0.134 g of 1% solution in water) was added into the mixture ink to adjust viscosity and to adjust sodium dopant. The ink was then stirred vigorously for 12 hours to form Ink 3.

A molybdenum coated soda-lime glass substrate is coated with Ink 3 by a rod coating method, and the coated substrate is vacuum dried at 220° C. for 2 hours. The dried substrate is put into a sufurization tube and heated to 480° C. for 30 minutes and followed with 510° C. for 2 hours under a stream of hydrogen sulfide (2% balanced in argon) with a flow speed of 0.5 mm/minute. The copper, indium in the film react with the selenium in the film and with the hydrogen sulfide in the atmosphere of the reaction tube to form a 2 μm film of CuInSeS. This film can form a light absorbing semiconducting layer for a thin film photovoltaic cell.

I claim:

1. A precursor ink for printing semiconductor photovoltaic cells comprising:
a plurality of particulates of one or more metal compounds selected from IB, IIB and IIIA
a liquid chalcogen solution
a functional solution

2. A precursor ink for printing semiconductor photovoltaic cells according to claim 1, wherein the metal compounds are oxide, chalcogenide, halide, hydroxide, carboxylic salt, nitrate, sulfonate, triflate of IB, IIB, and IIIA.

3. A precursor ink for printing semiconductor photovoltaic cells according to claim 1, wherein the metal compounds are compounds of copper, zinc, cadmium, indium, gallium, aluminum

4. A precursor ink for printing semiconductor photovoltaic cells according to claim 1, wherein the metal compounds are carboxylic salts with the carbon number less than 33.

5. A precursor ink for printing semiconductor photovoltaic cells according to claim 1, wherein the liquid chalcogen solution is the solution of trioctylphophine dissolved with chalcogen elements of S, Se or Te.

6. A precursor ink for printing semiconductor photovoltaic cells according to claim 1, wherein the liquid chalcogen solution is the solution of trioctylphophine dissolved with organic chalcogen with the formula of R1XR2 and/or R1XXR2, wherein X=S, Se, and R1/R2 are hydrocarbon with carbon number less than 12.

7. A precursor ink for printing semiconductor photovoltaic cells according to claim 1, wherein the functional solution is a solvent or solvent mixture function as viscosity adjustment and is selected from those containing heteroatom of N, P, O and the viscosity is preferably between 500 to 10,000 cp.

8. A precursor ink for printing semiconductor photovoltaic cells according to claim 1, wherein the functional solution is a solvent or solvent mixture function as stabilizing the ink particulates and is selected from those containing heteroatom of N, P, O.

9. A precursor ink for printing semiconductor photovoltaic cells according to claim 1, wherein the functional solution is a solvent or solvent mixture dissolved with a sodium ion dopant and function as a promoter for CIGS crystal growth.

10. A method for making a semiconductor film with the general formula Cu(InₐGa_{b}Al_{c})Se_{y}S_{2-y}, where 0.7<a+b+c<1.3 and 0≦y≦2, by the following steps:
a) Selenium, sulfur or both are dissolved in a liquid organic solvent. The chemical composition of this liquid organic solvent includes one or more of the elements phosphorus, sulfur and oxygen.
b) The liquid organic solvent produced in step a) is mixed with a plurality of particulates of metal sources or metal compounds selected from IB, IIB and IIIA.
c) Formulation a precursor ink by mixing a) and b) and a functional solution for adjusting viscosity, increasing ink stability and containing sodium ion to promoting CIGS crystal growth.
d) Apply the precursor ink c) on substrate and followed with a baking process under elevated temperature at vacuum.
e) Chalcogenize the baked film of d) at atmosphere of chalcogen vapor and/or at atmosphere of hydrogen chalcogenide to cause some of the components of the ink produced in step c) and deposited on a substrate in step d) to react and creating the desired polycrystalline semiconductor film.

11. A thin film photovoltaic cell in which a semiconducting layer is made as in claims 1 and 12.

12. A thin film photovoltaic cell as in claim 1 in which the semiconducting layer made as in claims 12 is the light-absorbing p layer of the device.

13. A photovoltaic module made up of photovoltaic cells as in claim 11.
